(19) United States
(12) Patent Application Publication
(10) Pub. No.: US 2026/0321559 A1
(43) Pub. Date: Oct. 15, 2026

(54) SPUTTERING TARGET BONDING METHOD AND TARGET ASSEMBLIES PRODUCED THEREBY

(71) Applicant: Honeywell International Inc., Charlotte, NC (US)

(72) Inventors: Suiqiong Li, Spokane, WA (US); Stephane Ferrasse, Spokane, WA (US); Nishanth Selvaraj, Sriracha (TH)

(21) Appl. No.: 19/286,444

(22) Filed: Jul. 31, 2025

Related U.S. Application Data
(60) Provisional application No. 63/788,629, filed on Apr. 14, 2025.

(51) Int. Cl. H01J 37/34; B23K 15/00; C23C 14/34

(52) U.S. Cl. CPC H01J 37/3423; B23K 15/0046; C23C 14/3407

(57) ABSTRACT

A method of forming a bond in a sputtering assembly includes forming first projections on a bonding surface of a sputtering target, forming second recesses on a bonding surface of a backing plate, aligning the sputtering target and the backing plate so that the first projections fit within the second recesses and the second projections fit within the first recesses to form an assembly, and applying pressure to the assembly so that first projections form an interlock bond between the sputtering target and the backing plate, wherein the interlock bond is void-free and wherein the backing plate having a greater hardness than the sputtering target.

### CROSS-REFERENCE TO RELATED APPLICATION

This application claims priority to Provisional Application No. 63/788,629, filed Apr. 14, 2025, which is herein incorporated by reference in its entirety.

### TECHNICAL FIELD

The present disclosure relates to a bonding assembly and a process for bonding a sputtering target assembly.

### BACKGROUND

Physical vapor deposition methodologies are used extensively for forming thin films of material over a variety of substrates. One area of importance for such deposition technology is semiconductor fabrication. A diagrammatic view of a portion of an exemplary physical vapor deposition (“PVD”) apparatus 8 is shown in FIG. 1. In one configuration, a sputtering target assembly 10 comprises a backing plate 12 having a target 14 bonded thereto. A substrate 18 such as a semiconductive material wafer is within the PVD apparatus 8 and provided to be spaced from the target 14. A surface 16 of target 14 is a sputtering surface. As shown, the target 14 is disposed above the substrate 18 and is positioned such that sputtering surface 16 faces substrate 18. In operation, sputtered material 22 is displaced from the sputtering surface 16 of target 14 and used to form a coating (or thin film) 20 over substrate 18.

A secure bond between the target 14 and the backing plate 12 is important for optimizing the sputtering processes and achieving high-quality thin-film coatings. Prior methods for bonding include soldering, brazing, diffusion bonding, clamping and by epoxy cement. Some methods do not provide a sufficient bond, while other methods, such as diffusion bonding result in undesirable grain size growth, particularly in sputtering targets having a low melting point, such as aluminum and copper.

An improved method for bonding sputtering target assemblies is needed.

### SUMMARY

In Example 1, a method of forming a bond in a sputtering assembly includes forming first projections on a bonding surface of a sputtering target, the first projections spaced from adjacent first projections by first recesses; forming second recesses on a bonding surface of a backing plate, the second recesses spaced from adjacent second recesses by a bonding surface and the second recesses including a first vertical portion and a first inclined or twisted portion in fluid communication with the first vertical portion; aligning the sputtering target and the backing plate so that the first projections fit within the second recesses and the second projections fit within the first recesses to form an assembly; and applying pressure to the assembly so that first projections form an interlock bond between the sputtering target and the backing plate, wherein the interlock bond is void-free and wherein the backing plate having a greater hardness than the sputtering target.

In Example 2, the method of Example 1 wherein the second recesses further include a second vertical portion, the first inclined or twisted portion located between the first vertical portion and the second vertical portion and the first vertical portion, the inclined or twisted portion and the second vertical portion are in fluid communication.

In Example 3, the method of Example 1 or Example 2 wherein the first inclined or twisted portion is an inclined portion which forms an angle to the first vertical portion.

In Example 4, the method of Example 3 wherein the angle is from about 90° to about 150°.

In Example 5, the method of any of Examples 1~4 wherein the first projections are concentric rings.

In Example 6, the method of Example 5 wherein the second recesses are concentric rings.

In Example 7, the method of any of Examples 1~4 wherein the first projections are radially and circumferentially spaced apart from adjacent first projections.

In Example 8, the method of any of Examples 1-7 and further comprising welding the sputtering target to the backing plate about a circumference of the assembly before applying pressure to the assembly.

In Example 9, the method of any of Examples 1-8 and further comprising forming a vacuum between the sputtering target and the backing plate before applying pressure to the assembly.

In Example 10, the method of any of Examples 1-9 wherein forming second recesses on the bonding surface of the backing plate includes connecting a first plate having first recesses to a second plate having second recesses which align with the first recesses.

In Example 11, the method of any of Examples 1-10 wherein the assembly is at room temperature during the step of applying pressure to the assembly.

In Example 12, the method of any of Examples 1-11 wherein the prior to applying pressure, a volume of a first projection is the same as or substantially similar to a volume of a corresponding second recess.

In Example 13, a sputtering target assembly includes a sputtering target having sputtering target projections; and a backing plate bonded to the sputtering target by a mechanical bond, the backing plate having backing plate recesses having a first vertical portion and an inclined portion and the sputtering target projections positioned within the backing plate recesses.

In Example 14, the sputtering target assembly of Example 13 wherein the backing plate recess includes a second vertical portion, the inclined portion positioned between the first vertical portion and the second vertical portion and the first vertical portion, the inclined portion and the second vertical portion in fluid communication.

In Example 15, the sputtering target assembly of Example 13 wherein the sputtering target projection includes a first vertical portion, a twist portion and a second vertical portion.

In Example 16, the sputtering target assembly of Example 13 wherein an outer radially portion of the sputtering target and backing plate are joined by a weld.

In Example 17, the sputtering target assembly of Example 13 wherein the inclined portion forms an angle of about 90° to about 150° with the first vertical portion.

In Example 18, the sputtering target assembly of Example 13 wherein the sputtering target projections are concentric rings.

In Example 19, the sputtering target assembly of Example 18 wherein the backing plate recesses are concentric rings.

In Example 20, the sputtering target assembly of any of Examples 13-19 wherein the bond between the sputtering target and the backing plate is void-free.

While multiple embodiments are disclosed, still other embodiments of the present invention will become apparent to those skilled in the art from the following detailed description, which shows and describes illustrative embodiments of the invention. Accordingly, the drawings and detailed description are to be regarded as illustrative in nature and not restrictive.

### BRIEF DESCRIPTION OF THE DRAWINGS

FIG. 1 is a schematic illustration of a sputtering apparatus.

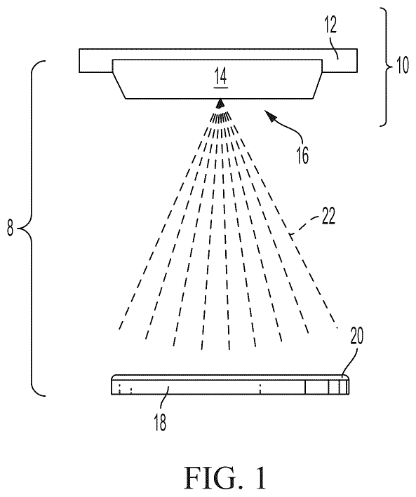

FIG. 2 is a cross-sectional view of a sputtering target assembly.

FIGS. 3A-3D are bottom views of various embodiments of a sputtering target.

FIG. 4 is a flow chart for a method of making the sputtering target of FIG. 2.

FIG. 5 is a cross-sectional view of a multi-piece backing plate.

FIG. 6A is a cross sectional, exploded view of the sputtering target assembly of FIG. 2 before bonding.

FIG. 6B is an enlarged view of a portion of FIG. 6A.

FIG. 7 is a cross-sectional view of the sputtering target assembly of FIG. 2 before bonding.

FIG. 8 is a cross-sectional view of an alternative sputtering target assembly.

FIG. 9A is a cross-sectional view of the sputtering target assembly of FIG. 8 before bonding.

FIG. 9B is an enlarged view of a portion of FIG. 9A.

FIG. 10 is a perspective view of a target projection after bonding.

### DETAILED DESCRIPTION

Disclosed herein is a sputtering target assembly joined by mechanical locking and a method of making the same. In some embodiments, the bond between the sputtering target and the backing plate is a low temperature bond, such as a bond that is formed at a temperature of about 38° C. or less.

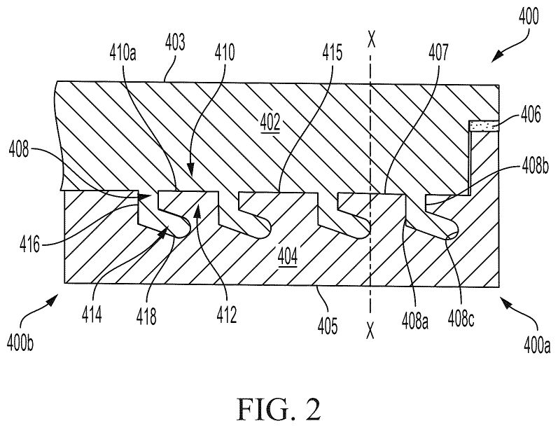

FIG. 2 is a cross-sectional schematic illustration of sputtering target assembly 400 which includes sputtering target 402, backing plate 404 and weld 406. Sputtering target assembly 400 is circular and include radially outward portion 400a and radially inward portion 400b. Radially inward portion 400b is closer to the center of sputtering target assembly 400 than radially outward portion 400a. Sputtering target 402 and backing plate 404 are joined at interlock bond 407. One skilled in the art will recognize that sputtering assembly 400 is an exemplary design and features, such as the surface profile of sputtering target 402 and/or the location of weld 406, can be changed.

Weld 406 attaches sputtering target 402 to backing plate 404. Weld 406 can be formed at radially outward edge 400a of sputtering target assembly 400. In some embodiments, weld 406 can extend the entire circumference of sputtering target 402 and backing plate 404. In some embodiments, weld 406 creates or maintains a vacuum between sputtering target 402 and backing plate 404. This assembly can also prevent contamination at the interface of sputtering target 402 and backing plate 404, for example during the bonding process described herein. In some embodiments, weld 406 can be at the radially outward or peripheral portion of sputtering assembly 400. However, weld 406 may be at different location or a vacuum can be created between sputtering target 402 and backing plate 404 using a different method.

Sputtering target 402 includes sputtering surface 403, target projections 408 (having side walls 408a and 408b and bonding surface 408c) and target recesses 410 (defined by side walls 408a and 408b and bonding surface 410a). Target projections 408 and target recesses 410 are located on the surface opposite sputtering surface 403. After bonding, as shown in FIG. 2, target projections 408 and target recesses 410 are adjacent to backing plate 404. Target projections 408 and target recesses 410 work with backing plate 404 to bond sputtering target 402 and backing plate 404.

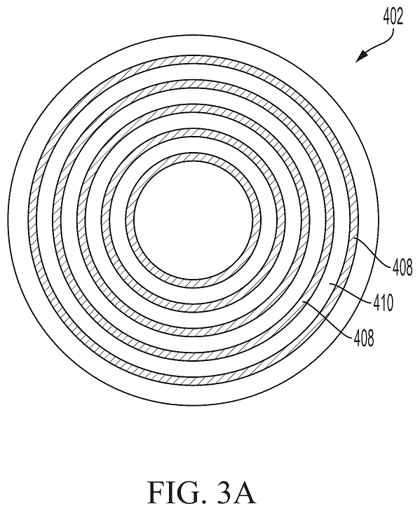

Target projections 408 extend opposite sputtering surface 403. Adjacent target projections 408 are separated from one another by target recesses 410. FIGS. 3A-3D are bottom views of various embodiments of sputtering target 402. One skilled in the art will recognize that backing plate 404 is configured to accept sputtering target 402. In FIG. 3A, target projections 408 and target recesses 410 can extend circumferentially, forming rings on sputtering target 402. For example, target projections 408 are radially space apart from one another by target recesses 410. In FIG. 3B, target projections 408 are discrete projections which do not individually extend the full circumference of sputtering target 402. Target projections 408 are spaced apart from adjacent target projections 408 in the radial and the circumferential directions by target recesses 410. In FIG. 3C, target projections 408 and target recesses 410 extend across sputtering target 402, for example in parallel straight lines. In FIG. 3D, target projections 408 are discrete projections which do not individually extend the full width of sputtering target 402. Target projections 408 are spaced apart from adjacent target projections 408 in the x-direction and γ-direction by target recesses 410.

Backing plate 404 includes back face 405, backing plate bonding surface 412 and backing plate recesses 414. Backing plate bonding surface 412 and backing plate recesses 414 are located on the surface opposite back face 405. Adjacent backing plate recesses 414 are separated from one another by backing plate bonding surfaces 412. In some embodiments, a single backing plate recess 414 extends circumferentially about backing plate 404. In this way, backing plate recesses 414 can form concentric rings or recesses in backing plate 404. In other embodiments, backing plate recesses 414 can be spaced apart from adjacent backing plate recesses in the radial and circumferential directions by backing plate bonding surfaces 412. In some embodiments, backing plate recesses 414 align with and are designed to accept target projections 408. For example, when target projections 408 are concentric rings, backing plate recesses 414 can be concentric rings. When target projections 408 are discrete projections, backing plate recesses 414 can be discrete recesses.

In FIG. 2, backing plate recesses 414 have a “L” cross-sectional shape. Backing plate recesses 414 can be formed by vertical portion 416 and inclined portion 418. Vertical portion 416 intersects with inclined portion 418 to form a continual recess or channel having recess end 420. In some embodiments, recess end 420 is has a rounded cross-section. In some embodiments, avoiding sharp corners at recess end 420 (i.e., having a rounded surface) can prevent the formation of voids. In some embodiments, vertical portion 416 is parallel to axis X-X extending through sputtering target assembly 400.

Inclined portion 418 can form an angle from about 90° to about 150° with vertical portion 416. In some embodiments, the angle formed can be measured by measuring the angle formed by the centerlines through each portion. For example, in FIG. 2, inclined portion 418 can form an angle of about 110° with vertical portion 416.

In some embodiments, sputtering target 402 is formed of a metal or metal alloy which is softer than backing plate 404; backing plate 404 is formed of a material, such as a metal or metal alloy, which is harder (i.e., has a higher yield strength) than sputtering target 402. Example materials for sputtering target 402 include aluminum, copper, titanium, aluminum alloys and copper alloys. Example materials for backing plate 404 include aluminum alloys such as Al2014, Al6061, Al2024 and copper alloys such as CuZn, CuCr and CuCrNiSi (C1800). The softer material (the material with lower yield strength, i.e., sputtering target 402 in this embodiment) is formed from a material that has a ductility which allows it to deform sufficiently during the interlock bonding process described herein. In some embodiments, the sputtering target, the backing plate or the sputtering target and the backing plate have a ductility of at least 5%. In some embodiments, having a ductility of at least 5% reduces or avoids cracking or other defects during the twist bonding process. The sputtering target and backing plate are also formed from materials having a sufficient difference in yield strength such that the softer material (i.e., sputtering target 402 in this embodiment) deforms sufficiently during the interlock bonding process described herein. In some embodiments, the yield strength of the sputtering target and the back plate differ by at least 50%.

TABLE 1
Example sputtering target materials

| | | | | | Hardness | |
|---|---|---|---|---|---|---|
| | | | | | HB (500 Kg | |
| | Tensile Strength | | Yield Strength | | Load/10 mm | Ductility |
| | (ksi/MPa) | | (ksi/MPa) | | ball) | (%) |
| Al/doped Al | 5-8 | 34-55 | 2-3 | 14-20 | <20 | >40 |
| Al0.5Cu | 13-15 | 90-103 | 7-8 | 40-50 | 24-26 | >30 |
| Cu | 31.9 | 220 | 13 | 90 | 45 | >25 |

TABLE 2
Example backing plate materials

| | | | | | Hardness | |
|---|---|---|---|---|---|---|
| | | | | | HB (500 Kg | |
| | Tensile Strength | | Yield Strength | | Load/10 mm | Ductility |
| | (ksi/MPa) | | (ksi/MPa) | | ball) | (%) |
| Al6061 T6 | 45 | 310 | 39.9 | 275 | 95 | 12 |
| Al2024 T8 | 70 | 485 | 65.3 | 450 | 128 | 6 |
| Al2024 T351 | 68.2 | 470 | 47.1 | 325 | 120 | 20 |
| C18000 | 89.9-100 | 620-690 | 65-75 | 450-520 | 158 | 14 |
| CuCr | 45.8-53.7 | 315-370 | 31-38 | 213-260 | | >25 |
| CuZn | 50-52 | 344-360 | 19-21.5 | 130-148 | | >40 |

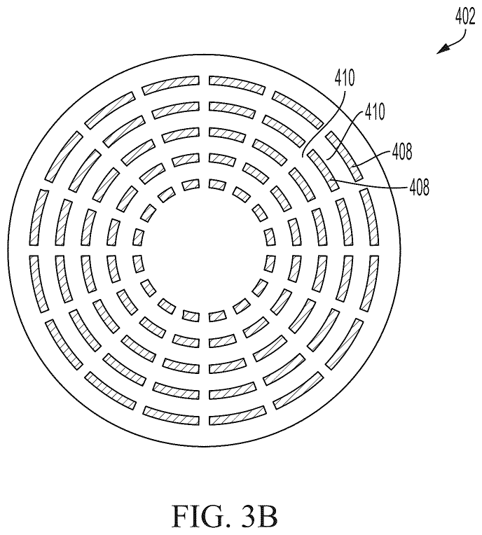

FIG. 4 is flow chart of method 200 for making sputtering assembly 400. In step 202, projections and recesses are formed on the sputtering target on the surface opposite the sputtering surface of the sputtering target. As described herein, these projections and recesses are strategically designed to allow for a uniform and void-free interlocking of the sputtering target and the backing plate. In some embodiments, material is removed from the sputtering target to form the projections and recesses. For example, circular grooves can be cut or machined into the sputtering target. The locations where material is removed from the sputtering target can form the recesses and the locations where material was not removed can form the projections.

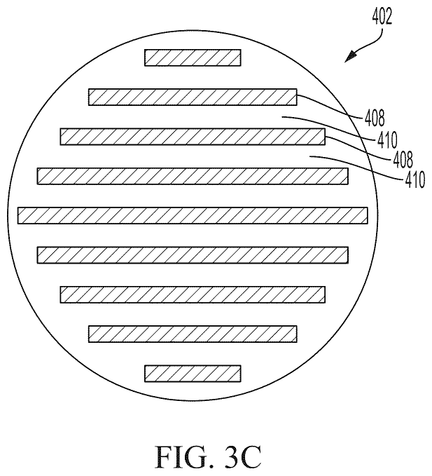

In step 204, recesses are formed on the backing plate on a surface opposite the back face of the backing plate. In some embodiments, material is removed from the backing plate to form the recesses. For example, material can be removed by machining, cutting, or drilling the recesses in the backing plate. In other embodiments, the backing plate may be cast, such as by near net shape casting, or formed by additive manufacturing, such as three-dimensional printing or otherwise formed with the recesses and projections. In some embodiments, the backing plate is formed of two or more pieces. With reference to FIG. 5, backing plate 404 can include first plate 404a and second plate 404b. First plate 404a contains through holes 316 which can be substantially vertical (parallel to axis X-X of FIG. 2). Second plate 404b contains recesses 318 having recess ends 420. Recesses 418 can form an angle from about 90° to about 150° with axis X-X. First plate 404a can be attached to second plate 404b to form backing plate 404. For example, first plate 404a and be attached to second plate 404b by welding, hot isostatic pressing (HIP), or solder bonding. When first plate 404a is attached to second plate 404b, through holes 316 can form or form a portion of vertical portions 416 and recesses 318 can form or form a portion of inclined portion 418. Together through holes 316 and recesses 318 form backing plate recesses 414 having recess ends 420.

One skilled in the art will recognize that steps 202 and 204 can occur in any order.

In step 206, a vacuum is created between the sputtering target and the backing plate. First, the sputtering target having the formed projections and recesses is aligned with the backing plate having the formed recesses. For example, the projections of the sputtering target are fit within the recesses of the backing plate. In this way, the sputtering target and the backing plate are positioned to create an interface defined by their mating surfaces. In some embodiments, a vacuum is then created between the sputtering target and backing plate. For example, a vacuum can be created by bonding the peripheral portion of this interface using E-beam welding or TIG weld under vacuum. In some embodiments, the weld or bond between the sputtering target and the backing plate can be made about the entire circumference of the sputtering target assembly. This peripheral bond can hold the assembly together during the interlock bond of the next step. Additionally, because the bond is created under vacuum, the atmospheric air between the backing plate and the sputtering target is removed. Thus, there is no air between the parts during the interlock bond of step 208.

In step 208, an interlock bond is formed between the sputtering target and backing plate. In some embodiments, the vacuum is maintained between the sputtering target and the backing plate during the bonding process. The bonding process can be a low temperature bond process. In some examples, the interlock bond can be formed by using a pressing or forging process. In some embodiments, the forge process can be performed with the sputtering target and backing plate at room temperature, about 20-22° C. For example, the pressing or forging can be performed at about room temperature. In other embodiments, the forging process is performed at a temperature above room temperature. In some embodiments, the process is performed at a temperature above room temperature and below the peak aging temperature of the sputtering target. In one example, the process is conducted when the sputtering target and backing plate are above room temperature and less than about 38° C. In another example, the sputtering target and/or backing plate can be heated (for example to about 300° C.) and then forged or isostatic pressed at the elevated temperature.

In one example, where the backing plate is an aluminum alloy, the aluminum alloy backing plate is heated treated before the forging step. In one embodiment, the harder material (i.e., the backing plate) can be heat treated at a temperature below the peak aging temperature of the material. For example, the aluminum alloy backing plate can be heat treated at temperature below the peak aging temperature (typical range is about 150-250° C. for about 2-12 hours for most aluminum alloy backing plate materials). Additionally, or alternatively, the softer material (i.e., the sputtering target) can be heat treated at temperatures above the peak aging temperature for the material. For example, an aluminum or aluminum alloy sputtering target can heat treated at about 250-350° C.; copper and copper alloy sputtering targets (i.e., Cu, CuAl, CuMn) can be heat treated at about 250° C.-550° C. for about 0.5-2 hours; titanium material can be heat treated at about 250-500° C. for about 0.5-1 hours.

When a material undergoes forging, it is pressed from the top, causing the material to deform primarily in a downward and outward direction. Forging can cause a three-dimensional change in shape such that the target projections deform to fill the backing plate recesses.

After the forging or pressing process, the assembly may be subjected to an optional rolling process. When a material is rolled, the material is passed between two rollers, which compress the material primarily in the horizontal direction. Thus, the rolling process primarily elongates the material. In some embodiments, a rolling process creates shear deformation along the bonding interface, which breaks the oxidation layers on either or both of the target and the backing plate and can improve the diffusion between the target and the backing plate and increase the bond strength.

As discussed herein, a material interlock bond is formed between the sputtering target and the backing plate. The bond between the sputtering target and the backing plate may be further strengthen or enhanced if there is also material diffusion between the sputtering target and the backing plate. For some metals, such as aluminum and aluminum alloys, an oxide layer quickly and/or easily forms on exposed surfaces and may prevent material diffusion. Breaking the oxide layer can improve the material diffusion and thus improve bonding between the sputtering target and backing plate.

In step 210, the sputtering target assembly can optionally be annealed. In some embodiments, an annealing process can further improve the bond strength. The annealing process causes material diffusion between the target and the backing plate. As discussed herein, material diffusion can further strengthen or enhance the bond between the sputtering target and the backing plate.

Because the material of sputtering target 402 is softer than the material of backing plate 404, sputtering target projections 408 can be squeezed into vertical portions 414a of backing plate recesses 414 prior to step 208. When sputtering target assembly 400 is pressed to form an interlocking bond in step 208, sputtering target projections 408 pass through the intersection of portions 414a and 414b and enter inclined portion 414b, causing the material of sputtering target projections 408 to undergo severe plastic deformation.

This process deforms relatively straight target projections 408 into hook-like structures, which may create a stronger mechanical bond with backing plate 404 than if target projections 408 retained their original substantially straight configuration. More specifically, inclined portion 418 can physically deform target projections 408 to create strong physical locking bond between sputtering target 402 and backing plate 404. Additionally, or alternatively, the process can lead to grain refinement and improvement in material strength, further improving bond strength. Additionally, or alternative, in some embodiments, the backing plate recesses are designed such that intense deformation by simple shear occurs during mechanical bonding as the target projections pass from the vertical portion of the backing plate recess to the inclined channel. In some embodiments, this can further strengthen the material.

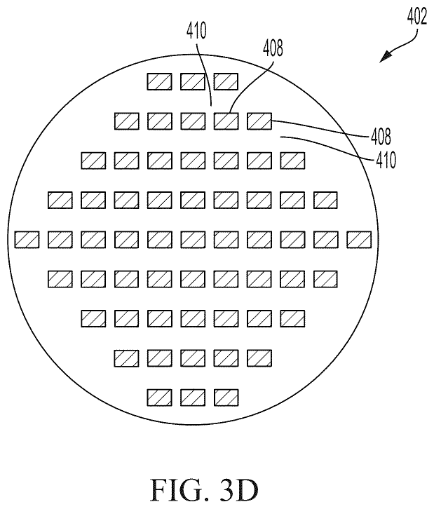

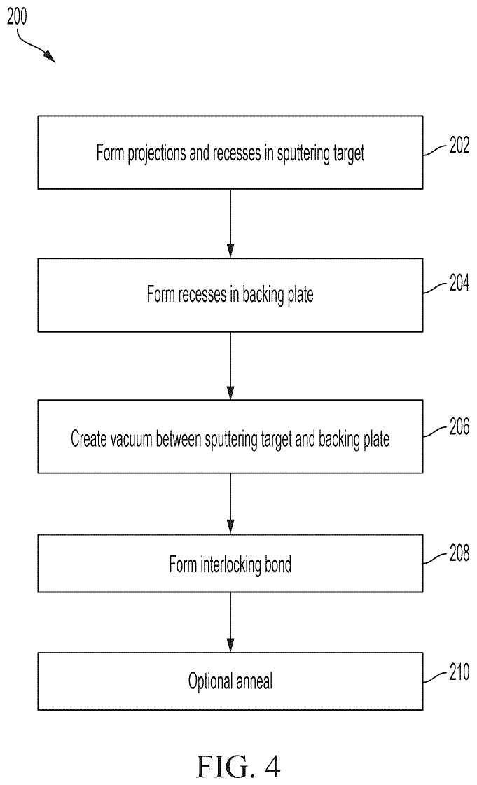

FIG. 6A is an exploded, cross-sectional schematic of sputtering target 402 and backing plate 404 after formation of target projections 408, target recesses 410 and backing plate recesses 414. FIG. 6B is an enlargement of a portion of FIG. 6A. Target projections 408 are formed by side walls 408a and 408b and bonding surface 408c, and target recesses 410 are defined by side walls 408a and 408b and bonding surface 410a. Target projections 408 and target recesses 410 can extend circumferentially, forming radially spaced rings on sputtering target 402. Target projections 408 and target recesses 410 are located on the surface opposite sputtering surface 403. Target projections 408 extend opposite sputtering surface 403. Adjacent target projections 408 are radially separated from one another by target recesses 410. Target projections 408 and target recesses 410 and backing plate bonding surface 412 and backing plate recesses 414 are designed to fit together. In some embodiments, target projections 408 and target recesses 410 fit together with backing plate bonding surface 412 and backing plate recesses 414 to form a uniform and void-free interlock between sputtering target 402 and backing plate 404.

The cross-sectional shape of target projections 408 can be any shape. In some embodiments, the cross-sectional shape of target projections 408 are square or rectangular. As described herein, the shape of target projections 408 is selected to result in a void-free bond. The height of target projections 408 is measured between bonding surface 410a of sputtering target recess 410 and bonding surface 408c of sputtering target projection 408. The height is designated as h₃ in FIG. 6B. In some embodiments, the height of target projections 408 is uniform. That is, each of target projections 408 have the same height. In other embodiments, target projections 408 can have different heights. For example, the height h₃ of the target projections 408 may decrease radially from the center of sputtering target 402 such that a target projection positioned closer to radially inner portion 400a will have a greater height than a target projection positioned closer to radially outer portion 400b.

The shape of target projections 408 is designed so that during the interlocking mechanical bonding process, target projections 408 deform and the material completely fills the spaces between sputtering target 402 and backing plate 404 creating a void-free bond. In some embodiments, the shape and size of target projections 408 is designed so that during the interlocking mechanical bonding process, target projections 408 deform and the material completely fills backing plate recesses 414 to create, for example, a void-free bond.

Backing plate recesses 414 can be formed by vertical portion 416 (having first wall 416a and second wall 416b) and inclined portion 418 (having first wall 418a and second wall 418b). Vertical portion 416 and inclined portion 418 are in fluid communication and form a conduit or recess.

First wall 416a can have height h₄ₐ which can be defined from bonding surface 412 to where first wall 416a intersects with first wall 418a of inclined portion 418. Second wall 416b can have height h_{4b} which can be measured from bonding surface 412 to where second wall 416b intersects with second wall 418b of inclined portion 418. First wall 416a of backing plate recess 414 can have a different height than second wall 416b. For example, height h₄ₐ of first wall 416a can be greater than height h_{4b} of second wall 416b. In some embodiments, height h₄ₐ can be greater than zero and height h_{4b} can be zero or greater than zero.

In some embodiments, sputtering target projections 408 can have width W₁. Target projections 408 can have any shape. Where target projections 408 are cylindrical, W₁ can be the diameter of sputter target projection 408. In some embodiments, width W₁ of sputtering target projection 408 can be consistent along the length of sputtering target projection 408. In other embodiments, W₁ can vary along the length of sputtering target projection 408. In some embodiments, each of sputtering target projections 408 can have the same width W₁. In other embodiments, one or more sputtering target projections 408 can have a different width W₁.

In some embodiments, vertical portion 416 can have width W₂ and inclined portion 418 can have width W₃. Width W₂ and width W₃ can be the same. In other embodiments, width W₂ and width W₃ can be different. In some embodiments, W₂ and width W₃ can differ by 15% or less, by 10% or less or by 5% or less. Vertical portion 416 and inclined portion 418 can have any shape. Wherein vertical portion 416 and inclined portion 418 are cylindrical, width W₂ and width W₃ are diameters. In some embodiments, width W₂ and width W₃ can be consistent along the length of backing plate recess 414. In other embodiments, width W₂ and width W₃ can vary along the length of backing plate recess 414. In some embodiments, each of backing plate recesses 414 can have the same widths W₂ and widths W₃. In other embodiments, one or more backing plate recesses 414 can have a different widths W₂ and widths W₃.

In some embodiments, width W₁ of target projection 408 can be less than the width W₂ of vertical portion 416 of backing plate recess 414, and target projections 408 can fit within backing plate recesses 414 to form an interlocking bond described herein. As described herein, target projections 408 are formed in sputtering target 402 and backing plate recesses 414 are formed in backing plate 404 before sputtering target 402 and backing plate 404 are joined. When sputtering target 402 and backing plate 404 are joined, target projections 408 deform and fill backing plate recesses 414 forming bonding layer 415 at the interface of sputtering target 402 and backing plate 404. The bond is void-free as can be determined using C-Scan.

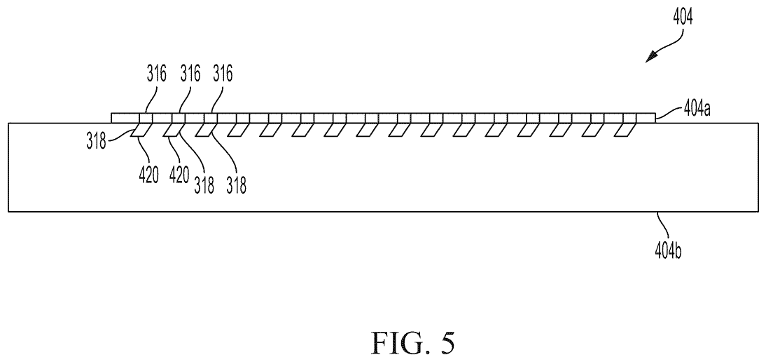

FIG. 7 is a cross-sectional schematic illustration of sputtering target 402 aligned with backing plate 404 after Step 206 and before Step 208. As shown, backing plate bonding surfaces 412 fit within target recesses 410 and target projections 408 fit within backing plate recesses 414. When the parts are forged, target projection 408 will deform and fill backing plate recesses 414 and form an interlocking bond. In some embodiments, height h₃ of sputtering target projections 408 is greater than height h₄ₐ of backing plate recess 414. In some embodiments, bonding surface 412 of backing plate 404 does not touch bonding surface 410a of target recess 410 before the forging process. As described herein, immediately prior to bonding, the space between sputtering target 402 and backing plate 404 may be void of atmospheric air.

In some embodiments, the volume of a target projection 408 is the same as or substantially similar to the volume of backing plate recess 414 to which it is aligned. In some embodiments, substantially similar to means within about ±0.5% or ±1%. In this way, target projection 408 can fill or substantially fill backing plate recess 414 to which it is aligned during the forging process.

In some embodiments, as shown in FIG. 7, weld 406 can be present at the radially outer portion 400a of sputtering target assembly 400. Weld 406 can extend the entire circumference of sputtering target assembly 400.

When the interlocking mechanical bond is formed in step 208, for example by pressing, target projections 408 of sputtering target 402 deform and fill up the spaces between sputtering target 402 and backing plate 404 as shown in FIG. 2. Inclined portion 418 creates a further locking of backing plate 404 to sputtering target 402.

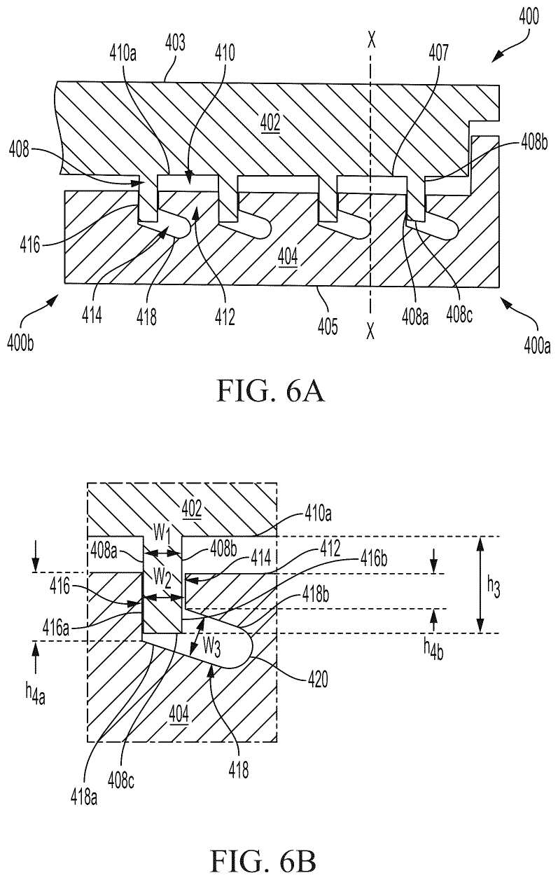

FIG. 8 is a cross-sectional schematic illustration of an alternative embodiment showing sputtering target assembly 500 having sputtering target 502, backing plate 504 and weld 506. Sputtering target 502 can be formed of a softer material than backing plate 504 as described herein for sputtering target 402 and backing plate 404. Weld 506 is similar to weld 406 and sputtering target assembly 500 can be formed according to method 200.

Sputtering target projections 508 and sputtering target recesses 510 are similar to sputtering target projections 408 and sputtering target recesses 410. Backing plate recesses 514 are similar to backing plate recesses 414 except that backing plate recesses 514 include two vertical portions, first vertical portion 516 and second vertical portion 517, and inclined portion 518. As shown in FIG. 8, inclined portion 518 can form an angle of about 90° to about 150° with first vertical portion 516. Inclined portion 518 is positioned between first vertical portion 516 and second vertical portion 517 and these create a channel having end 520. End 520 is similar to end 420. In further embodiments, additional inclined portions (similar to inclined portion 518) and/or vertical portions (similar to vertical portion 517) may be connected to second vertical portion 517. In some embodiments, backing plate recess has a vertical portion at the surface of backing plate 504 to accept sputtering target projection 508 and vertical portions and inclined portions are arranged and connected in an alternating pattern to form a channel ending at end 520.

When sputtering target assembly 500 is pressed to form an interlocking bond in step 208, sputtering target projections 508 pass through first vertical portion 516, inclined portion 518 and then second vertical portion 517. The change in angle to sputtering target projections 508 forced by inclined portions 518 results in severe plastic deformation of sputtering target projections 508 and forms a strong bond between sputtering target 402 and backing plate 404.

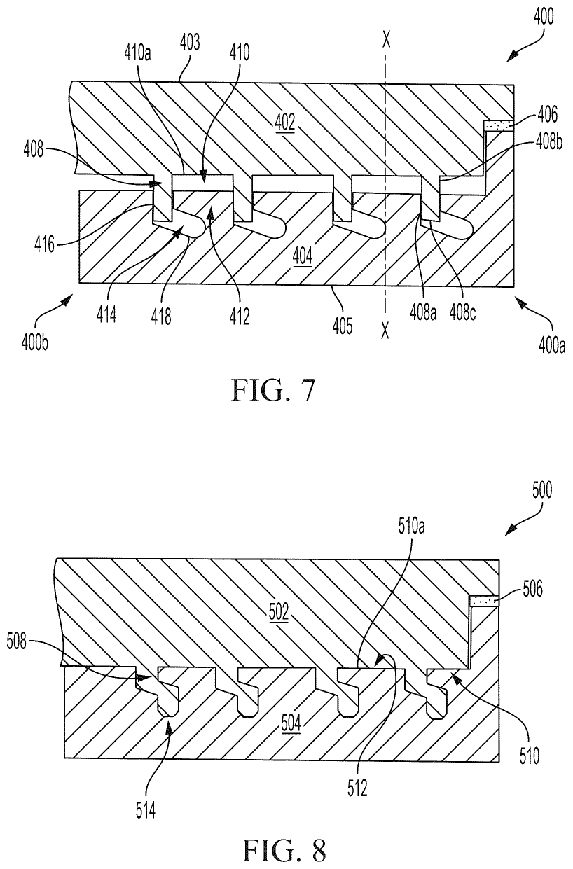

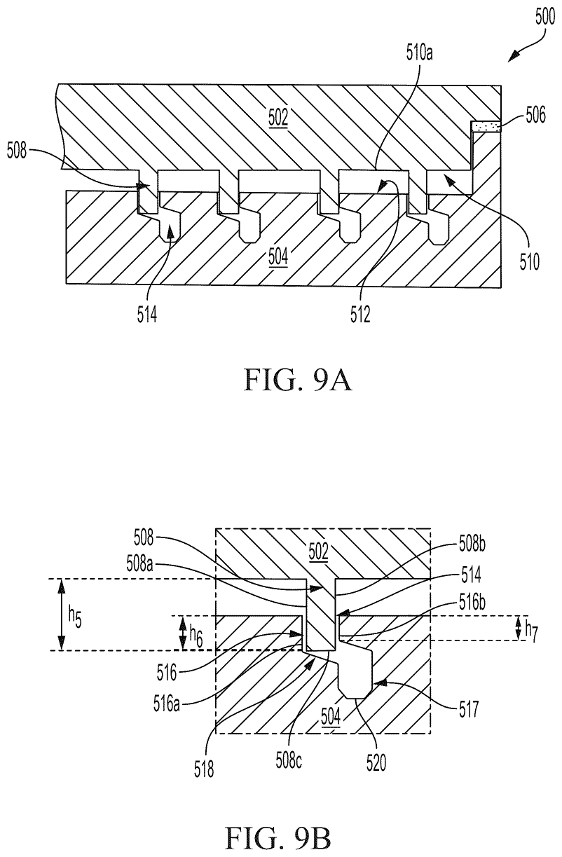

FIG. 9A is a cross-sectional schematic illustration of sputtering target 502 aligned with backing plate 504 after Step 206 and before Step 208, and FIG. 9B is an enlargement of a portion of FIG. 9A. Backing plate recess 514 includes first vertical portion 516 (having first wall 516a and second wall 516b), inclined portion 518 (having first wall 517a and second wall 518b) and second vertical portion 517 (having first wall 517a and second wall 517b).

As shown, backing plate bonding surfaces 512 fit within target recesses 510 and target projections 508 fit within backing plate recesses 514 to form an interlocking mechanical bond described herein. When the parts are forged, target projection 508 will deform and fill backing plate recesses 514. In some embodiments, height h₅ of sputtering target projections 508 is greater than height h₆ of first vertical 516. In some embodiments, bonding surface 512 of backing plate 504 does not touch bonding surface 510a of target recess 510 before the forging process. In some embodiments, atmospheric air is removed from the space between sputtering target 502 and backing plate 504 before the pieces are bonded together.

In some embodiments, the volume of a target projection 508 is the same as or substantially similar to the volume of backing plate recess 514 to which it is aligned. In this way, target projection 508 can fill or substantially fill backing plate recess 514 to which it is aligned during the forging process.

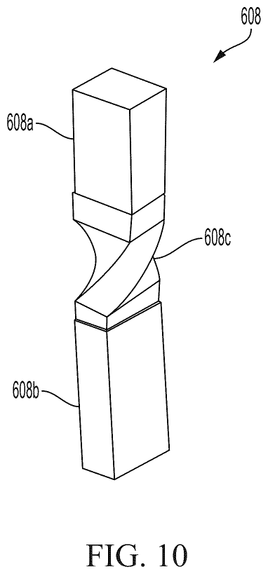

In an alternative embodiment, inclined portion 518 can be replaced with a portion which has a twisted surface structure, and which may or may not be generally vertical in orientation. FIG. 10 is a three-dimensional illustration of a sputtering target projection 608 which can be formed by pressing sputtering target projection 608 into such an alternative backing plate recess. One skilled in the art will recognize that sputtering target projection 608 is an inverse image of a backing plate recess which would form the shape. In some embodiments, sputtering target projections 608 can have a circular, square, or rectangular cross-sectional shape. Sputtering target projection 608 includes two vertical portions, first vertical portion 608a and second vertical portion 608b. The vertical portions are separated by twisted portion 608c. First vertical portion 608a and second vertical portion 608b can have substantially smooth outer surfaces. In comparison, the outer surface of twisted portion 608c has a twist and is not smooth. When a sputtering assembly is pressed in step 208, the sputtering target projections pass through a twisted portion in the backing plate recesses. The twist in the backing plate recess causes the sputtering target projection to plastically deform. In some embodiments, the twist may cause more plastic deformation to the sputtering target projection than the inclined portion(s) of sputtering target assembly 400 or 500. The resulting bonded sputtering target projection 608 includes twisted portion 608c and a strong bond is created between the sputtering target and the backing plate.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the above-described features.

What is claimed is:

1. A method of forming a bond in a sputtering assembly, the method comprising:
forming first projections on a bonding surface of a sputtering target, the first projections spaced from adjacent first projections by first recesses;
forming second recesses on a bonding surface of a backing plate, the second recesses spaced from adjacent second recesses by a bonding surface and the second recesses including a first vertical portion and a first inclined or twisted portion in fluid communication with the first vertical portion;
aligning the sputtering target and the backing plate so that the first projections fit within the second recesses and the second projections fit within the first recesses to form an assembly; and
applying pressure to the assembly so that first projections form an interlock bond between the sputtering target and the backing plate, wherein the interlock bond is void-free and wherein the backing plate having a greater hardness than the sputtering target.

2. The method of claim 1 wherein the second recesses further include a second vertical portion, the first inclined or twisted portion located between the first vertical portion and the second vertical portion and the first vertical portion, the inclined or twisted portion and the second vertical portion are in fluid communication.

3. The method of claim 1 wherein the first inclined or twisted portion is an inclined portion which forms an angle to the first vertical portion.

4. The method of claim 3 wherein the angle is from about 90° to about 150°.

5. The method of claim 1 wherein the first projections are concentric rings.

6. The method of claim 5 wherein the second recesses are concentric rings.

7. The method of claim 1 wherein the first projections are radially spaced apart from adjacent first projections.

8. The method of claim 1 and further comprising welding the sputtering target to the backing plate about a circumference of the assembly before applying pressure to the assembly.

9. The method of claim 1 and further comprising forming a vacuum between the sputtering target and the backing plate before applying pressure to the assembly.

10. The method of claim 1 wherein forming second recesses on the bonding surface of the backing plate includes connecting a first plate having first recesses to a second plate having second recesses which align with the first recesses.

11. The method of claim 1 wherein the assembly is at room temperature during the step of applying pressure to the assembly.

12. The method of claim 1 wherein the prior to applying pressure, a volume of a first projection is the same as or substantially similar to a volume of a corresponding second recess.

13. A sputtering target assembly comprising:
a sputtering target having sputtering target projections; and
a backing plate bonded to the sputtering target by a mechanical bond, the backing plate having backing plate recesses having a first vertical portion and an inclined portion and the sputtering target projections positioned within the backing plate recesses.

14. The sputtering target assembly of claim 13 wherein the backing plate recess includes a second vertical portion, the inclined portion positioned between the first vertical portion and the second vertical portion and the first vertical portion, the inclined portion and the second vertical portion in fluid communication.

15. The sputtering target assembly of claim 13 wherein the sputtering target projection includes a first vertical portion, a twist portion and a second vertical portion.

16. The sputtering target assembly of claim 13 wherein an outer radially portion of the sputtering target and backing plate are joined by a weld.

17. The sputtering target assembly of claim 13 wherein the inclined portion forms an angle of about 90° to about 150° with the first vertical portion.

18. The sputtering target assembly of claim 13 wherein the sputtering target projections are concentric rings.

19. The sputtering target assembly of claim 18 wherein the backing plate recesses are concentric rings.

20. The sputtering target assembly of claim 1 wherein the bond between the sputtering target and the backing plate is void-free.
